(19) United States
(12) Patent Application Publication
(10) Pub. No.: US 2006/0272935 A1
(43) Pub. Date: Dec. 7, 2006

(54) Multiple scanning magnetrons

(75) Inventors: Hien-Minh Huu Le, San Jose, CA (US); Akihiro Hosokawa, Cupertino, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: APPLIED MATERIALS, INC.

(21) Appl. No.: 11/146,762

(22) Filed: Jun. 6, 2005

(51) Int. Cl. C23C 14/32; C23C 14/00

(52) U.S. Cl. 204/192.1; 204/298.16; 204/298.22

(57) ABSTRACT

A sputter reactor configured for magnetron sputtering from a rectangular target onto a rectangular panel and including multiple magnetrons independently scannable across the back of the target. In one embodiment, the magnetrons scan only along paths parallel to one axis. A system controller may control actuators providing the mechanical movement and also control the amount of power delivered to the target in synchronism to the mechanical movement. The invention also includes scanning a magnetron in a rectangular path about the back of the rectangular target.

### FIELD OF THE INVENTION

The invention relates generally to sputtering of materials. In particular, the invention relates to the magnetron creating a magnetic field to enhance sputtering.

### BACKGROUND ART

Over the past decade, the technology has been intensively developed for fabricating flat panel displays, such as used for computer displays and more recently for television screens. Sputtering is the preferred approach in the fabrication of flat panels for depositing conductive layers including metals such as aluminum and transparent conductors such as indium tin oxide (ITO). The panels may include both thin film transistors (TFTs) and electrodes and other structure for liquid crystal display (LCD) displays, organic light emitting diodes, (OLEDs), plasma displays, and electron emission displays. Glass substrates are most typically used but other substrates, such as polymeric sheets, are being contemplated.

Flat panel sputtering is principally distinguished from the long developed technology of wafer sputtering by the large size of the substrates and their rectangular shape. Demaray et al. describe such a flat panel sputter reactor in U.S. Pat. No. 5,565,071, incorporated herein by reference in its entirety. Their reactor includes, as illustrated in the schematic cross section of FIG. 1, a rectangularly shaped sputtering pedestal electrode 12 for holding a rectangular glass panel 14 or other substrate in opposition to a rectangular sputtering target 16 within a vacuum chamber 18. The target 16, at least the surface of which is composed of a metal to be sputtered, is vacuum sealed to the vacuum chamber 18 across an isolator 20. Typically, a layer of the material to be sputtered is bonded to a backing plate in which cooling water channels are formed to cool the target 16. A sputtering gas, typically argon, is supplied into the vacuum chamber 18 held at a pressure in the milliTorr range. Advantageously, a back chamber 22 is vacuum sealed to the back of the target 16 and vacuum pumped to a low pressure, thereby substantially eliminating the pressure differential across the target 16 and its backing plate. Thereby, the target assembly can be made much thinner. When a DC power supply 23 applies a negative DC bias to the conductive target 16 with respect to the pedestal electrode 12 or other grounded parts of the chamber such as wall shields or the grounded chamber 18, the argon is ionized into a plasma. The positive argon ions are attracted to the target 16 and sputter metal atoms from it. The metal atoms are partially directed to the panel 14 and deposit thereon a layer at least partially composed of the target metal. Metal oxide or nitride may be deposited in a process called reactive sputtering by additionally supplying oxygen or nitrogen into the chamber 18 during sputtering of the metal.

To increase the sputtering rate, a linear magnetron 24, also illustrated in schematic bottom view in FIG. 2, is placed in back of the target 16. It has a central pole 26 of one vertical magnetic polarity surrounded by an outer pole 28 of the opposite polarity to project a magnetic field within the chamber 18 and parallel to the front face of the target 16. The two poles 26, 28 are separated by a substantially constant gap 30 over which a high-density plasma is formed adjacent the sputtering face of the target 16 inside the chamber 18 under the correct chamber conditions. The plasma flows adjacent the target 16 in a close loop or track. The outer pole 26 consists of two straight portions 32 connected by two semi-circular arc portions 34. The magnetic field traps electrons and thereby increases the density of the plasma and as a result increases the sputtering rate. The relatively small widths of the linear magnetron 24 and of the gap 30 produces a higher magnetic flux density. The closed shape of the magnetic field distribution along a single closed track forms a plasma loop generally following the gap 30 and prevents the plasma from leaking out the ends. However, the small size of the magnetron 24 relative to the target 16 requires that the magnetron 24 be linearly and reciprocally scanned across the back of the target 16. Typically, a lead screw mechanism drives the linear scan, as disclosed by Halsey et al. in U.S. Pat. No. 5,855,744 in the context of a more complicated magnetron. Although horseshoe magnets may be used, the preferred structure includes a large number of strong cylindrical magnets, for example, of NdBFe arranged in the indicated pole shapes with their orientations inverted between the two indicated polarities. Magnetic pole pieces may cover the operating faces to define the pole surfaces and a magnetic yoke bridging the two poles 26, 28 may couple the other sides of the magnets.

The described magnetron was originally developed for rectangular panels having a size of about 400 mm×600 mm. However, over the years, the panel sizes have continued to increase, both for economy of scale and to provide larger display screens. Reactors are being developed to sputter onto panels having a size of about 2 m×2 m. One generation of equipment processes a panel having a size of 1.87 m×2.2 m and is called 40K because its total area is greater than 40,000 cm². A follow-on generation called 50K has a size of greater than 2 m on each side. The widths of linear magnetrons are generally constrained to be relatively narrow if they are to produce a high magnetic field. As a result, for larger panels having minimum dimensions of greater than 1.8 m, linear magnetrons become increasingly ineffective, requiring longer deposition periods to uniformly sputter the larger targets.

### SUMMARY OF THE INVENTION

One aspect of the invention includes a magnetron sputtering system and a magnetron target assembly having a generally rectangular target and plural magnetrons independently scannable over a back of the target. For example, two or more magnetrons may be arranged along a first axis and be separately scannable along separate second axes perpendicular to the first axis.

Separate actuators may control the movement and speed of the plural magnetron under the overall control of a control system which may also control the power delivered to the target in synchronism with the magnetron movement. The magnetron speed may vary over a scan across the target either in a symmetric pattern with respect to the target median or an asymmetric pattern to account for other conditions and effects.

The invention also includes a magnetron that is scannable in two dimensions across the back of the target in a rectangular path having two perpendicular sets of parallel sides. The power may be turned off while the magnetron scans along one of the two perpendicular sets or may be otherwise varied during the scan.

### BRIEF DESCRIPTION OF THE DRAWINGS

FIG. 1 is a schematic cross-sectional view of a convention magnetron sputter reactor.

FIG. 2 is a plan view of a conventional linear racetrack magnetron.

FIG. 3 is a schematic plan view of a first embodiment of a two-dimensional scan mechanism for scanning of a magnetron across a rectangular target.

FIG. 4 is a plan view of a plan view of a substantially rectangular magnetron.

FIG. 5 is an orthographic view of a second embodiment of a two-dimension scan mechanism.

FIG. 6 is a plan view of a double-Z two-dimensional scan pattern.

FIG. 7 is a plan view of a rectangular two-dimensional scan pattern.

FIG. 8 is a schematic plan view of two independently linearly scannable magnetrons.

FIG. 9 is a schematic plan view of a variation of FIG. 8.

FIG. 10 is a schematic plan view of three independently linearly scannable magnetrons.

FIG. 11 is a schematic plan view of dividing the scan dimension into multiple zone for the variation of scan speed or target power.

FIG. 12 is a control diagram for the scanning mechanism and the target powering.

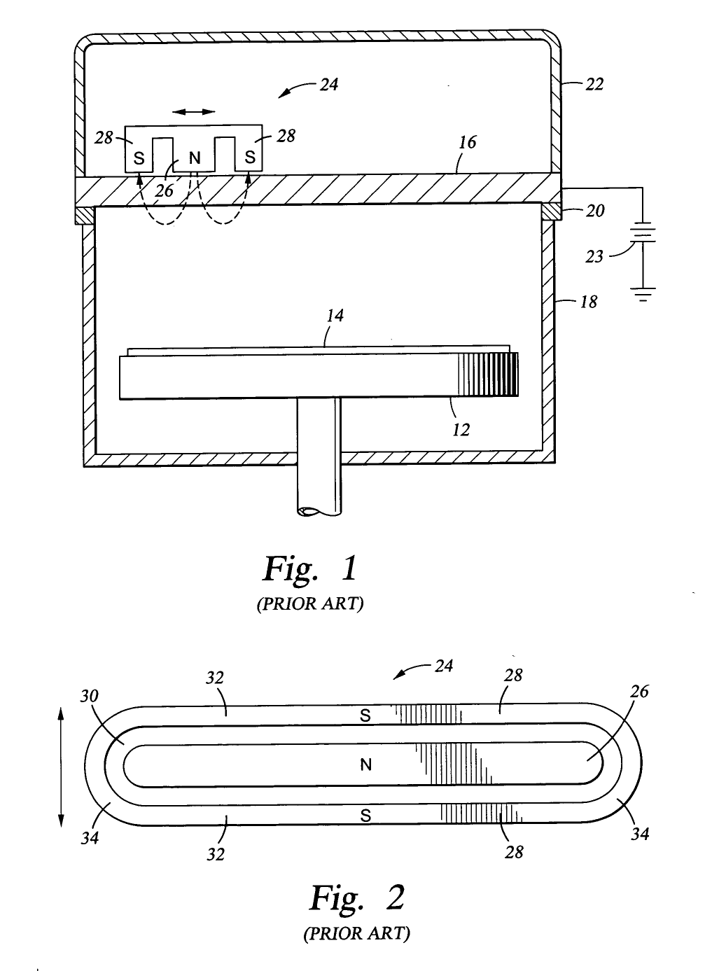

### DETAILED DESCRIPTION OF THE PREFERRED EMBODIMENTS

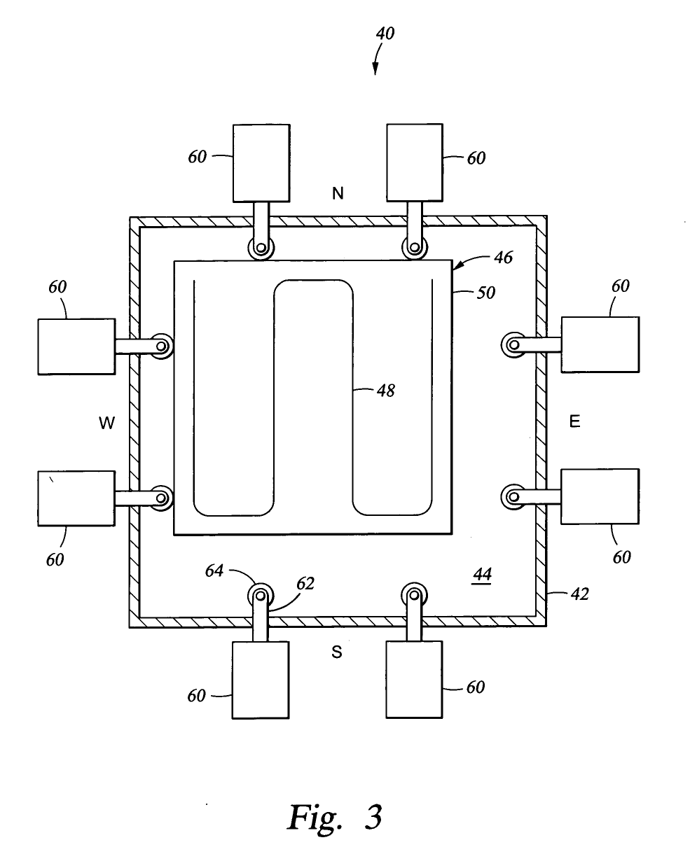

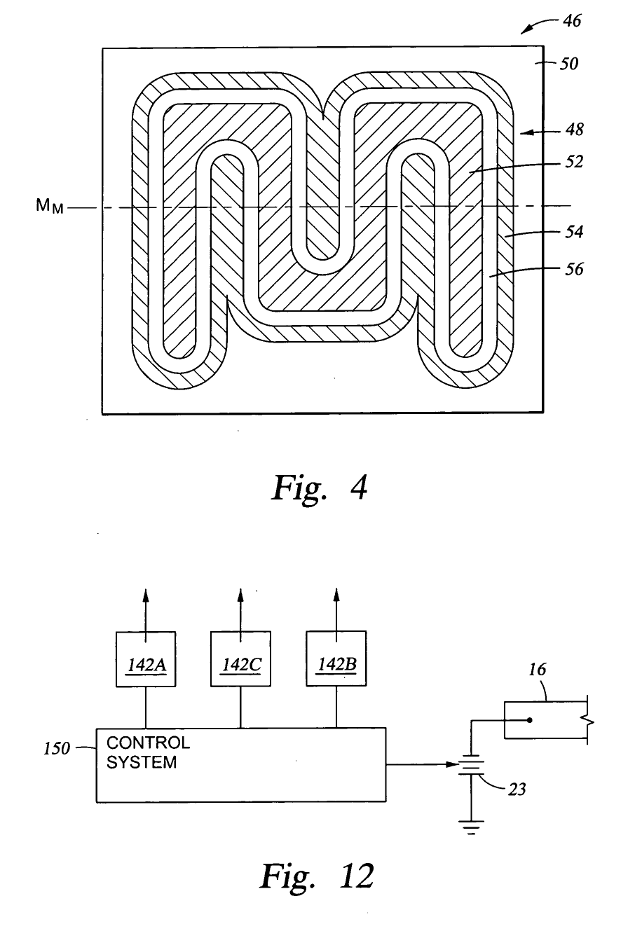

In U.S. patent application Ser. No. 10/863,152, filed Jun. 7, 2004, incorporated herein by reference in its entirety, Tepman discloses a two-dimensionally scanned magnetron 40 schematically illustrated in the partially sectioned plan view of FIG. 3. It includes a rectangular frame 42 supporting a target backing plate 44. A magnetron 46 is slidably supported at the back of the backing plate 44. As illustrated in the bottom plan view of FIG. 4, a convolute magnet assembly 48 is formed in a magnetron plate 50 to support a convolute plasma loop in the processing region adjacent the front of the target bonded to the backing plate. The convolute magnet assembly 48 includes an inner magnetic pole face 52 of one vertical magnetic polarity surrounded by an outer magnetic pole face 54 of the opposed vertical magnetic polarity. A gap 56 of substantially constant width separates the two pole faces 52, 54 and forms a closed band. Unillustrated magnets of the two polarities underlie the two pole faces 52, 54. The magnetron plate 48 supports the magnets and pole faces 52, 54 and, being composed of a magnetic material, also acts as a magnetic yoke coupling the magnets of opposite polarities. The magnet assembly 48 creates a magnetic field between the opposed the pole faces 52, 54. The magnetic field is in large part horizontal in the area overlying the gap 56 and creates a closed plasma loop of the closed convolute shape of the gap 56 on the face of the sputtering target.

Returning to FIG. 3, the magnetron plate 50 is smaller than the area of the target subject to the magnetic field of the scanned magnetron. Eight actuators 60 are arranged in pairs along the four sides of the rectangular frame 42. The paired actuators 60 are controlled alike to execute a same extension of associated rods 62. The pairing is preferred when the there is no fixed coupling between the actuators 60 and the magnetron plate 50 but only a pushing force is executed. A preferred coupling from the rods 62 of the actuators 60 include respective wheels 64 or other rotatable member on the end of each actuator rod 62. However, soft pusher pads, for example of Teflon, may be substituted for the wheels 64. Only a pair of wheeled actuator rods 62 need to engage the magnetron plate 50 to move the magnetron 46 a Cartesian direction.

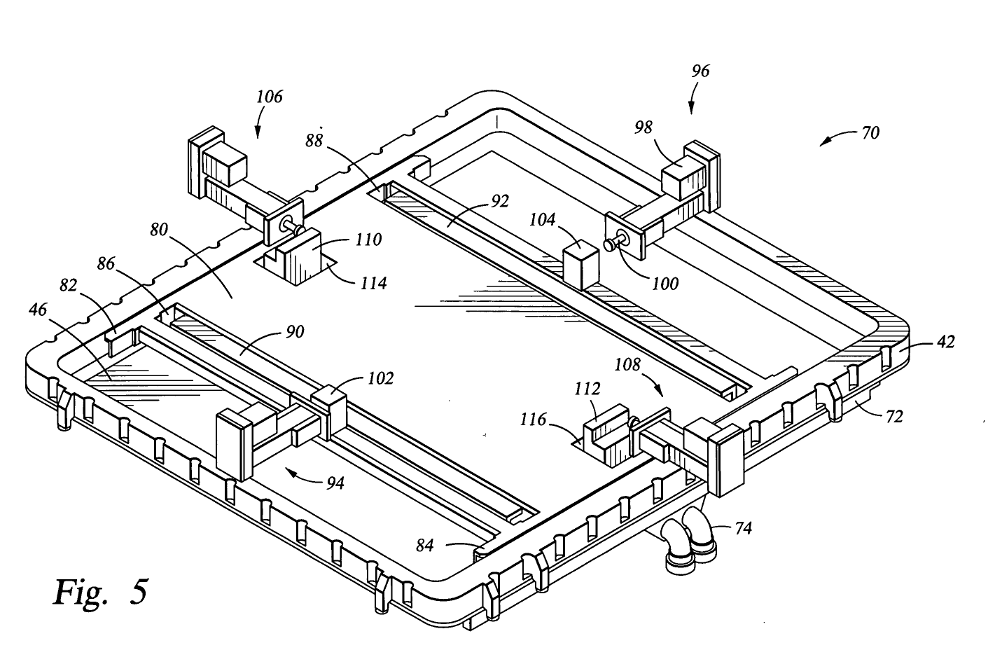

Another scan mechanism 70, illustrated orthographically in FIG. 5, is supported on the frame 42, which in turn is supported on the periphery of the target backing plate 46. A cooling manifold 72 distributes cooling fluid from supply lines 74 to cooling channels formed inside the target backing plate 46. A slider plate 80 includes two inverted side rails 82, 84 which slide in a first direction along and on top of respective series of wheel bearings mounted on the frame 42. Two slits 86, 88 are formed in the slider plate 80 to extend in the perpendicular second direction. Two inverted rails 90, 92 supporting the magnetron plate 50 beneath the slider plate 80 extend through the two slits 86, 88 are slidably supported on respective series of wheel bearings mounted on the slider plate 80 to allow motion in the second direction. That is, the magnetron plate 50 and associated magnetron 46 can slide in the perpendicular first and second directions. Further, the heavy magnetron is supported on the frame 42 and the periphery of the target backing plate, itself directly supported on the chamber wall, and not on the relatively thin cantilevered inner portions of the target and target backing plate.

A first set of actuators 94, 96 opposed along the direction of the slider rails 82, 84 are supported on the frame 42 and include respective independently controlled bidirectional motors 98, gear boxes, and worm gears driving pusher rods 100, which selectively abut, engage, and apply force to respective bosses 102, 104 extending upwardly from the slider plate 80. A second set of similarly configured actuators 106, 108 opposed along the direction of the magnetron rails 90, 92 are supported on the frame 42 to selectively engage respective bosses 110, 112 fixed to the magnetron magnetron plate 50 and extending upwardly through holes 114, 116 in the slider plate 80.

The two sets of actuators 94, 96, 106, 108 can be used to move the magnetron plate 50 and associated magnetron 46 in orthogonal directions. The bosses 110, 112 fixed to the magnetron plate 50 have relatively wide faces so that the associated actuators 106, 108 and pusher rods 100 can engage them as the other set of actuators 94, 96 are moving the magnetron plate 50 in the transverse direction.

It is possible to use a rigid connection between a bi-directional actuator and the magnetron plate 50 so that each set of actuator need comprise only a single actuator.

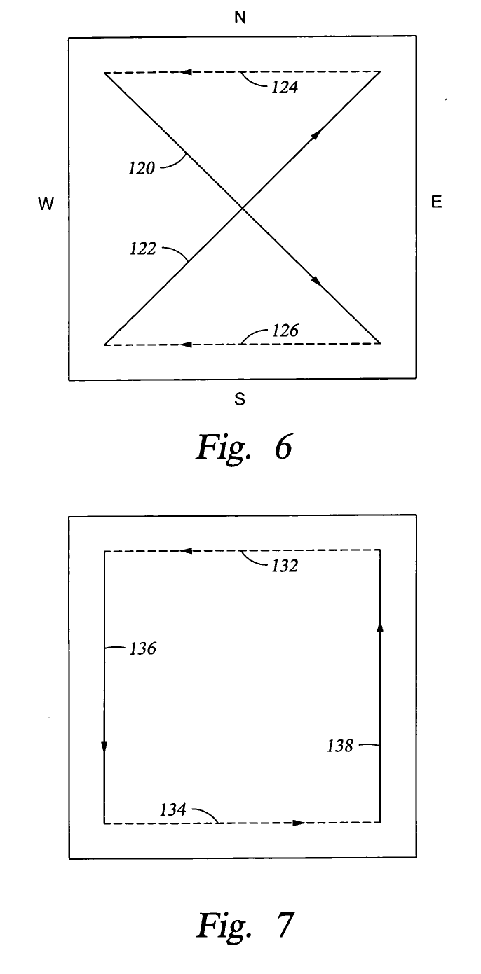

Tepman discloses several specific scanning patterns, including the double-Z pattern illustrated in the plan view of FIG. 6 in which the magnetron is scanned in a closed pattern within a rectangular scanning space which may be substantially smaller than the scanned target area since the illustrated rectangular magnetron is only somewhat smaller than the area of the target being scanned. Some scanning is desired to average out the sputtering caused by the finite width of the plasma loop. That is, the scanning should extend approximately over at least half the distance between neighboring parallel portions of plasma loop. The scanning pattern includes two diagonals 120, 122 and two opposed sides 124, 126 of the rectangular scanning space. In view of the fact that the magnetron plate 50 is typically only somewhat smaller than the target, for example, having dimensions between 50% and 90% of the target, the illustrated scan patterns do not extend over the entire area of the target but need extend over an area accounting for the difference in sizes between magnetron plate 50 (actually the effective area of the magnetron's magnetic field) and the useful area of the target. Tepman also states that the two-dimensional scanning pattern may be arbitrarily chosen.

Another advantageous scanning pattern illustrated in the plan view of FIG. 7 has four perpendicularly arranged pairs of parallel sides 132, 134 and 136, 138 aligned to the sides of the frame 42. The power to the target can be maintained along all four sides of the scan. However, since the scan along the principal linear direction of the convolute plasma loop does not average over the pitch of the convolute loop, the power may be turned off during the scanning on the sides 132, 134 parallel to the principal linear direction of the plasma loop and turned on during the perpendicular scanning along sides 136, 138 transverse to the principal linear direction. Alternatively, the power may be varied in a more complex schedule as the magnetron scans along the rectangular path.

The previously described magnetrons are relatively large. In view of the magnets, magnetic pole faces, and magnetic plate, they are relatively heavy. The weight introduces several problems. Heavy-duty gantries are required to install the magnetron and its scanning apparatus to the sputtering chamber and remove them for maintenance. Further, the weight of the magnetron either necessitates high torque motors or limits the speed of scanning. Slow scanning is a particular problem when only relatively thin films are being deposited, for example, less than 50 nm. The deposition may be completed before the scanning has been performed over sufficient target area to average the deposition thickness. Further, the scan patterns available for a single large movable magnetron are limited and do not permit easily achieving different sputtering rates between the center and the edge of the target.

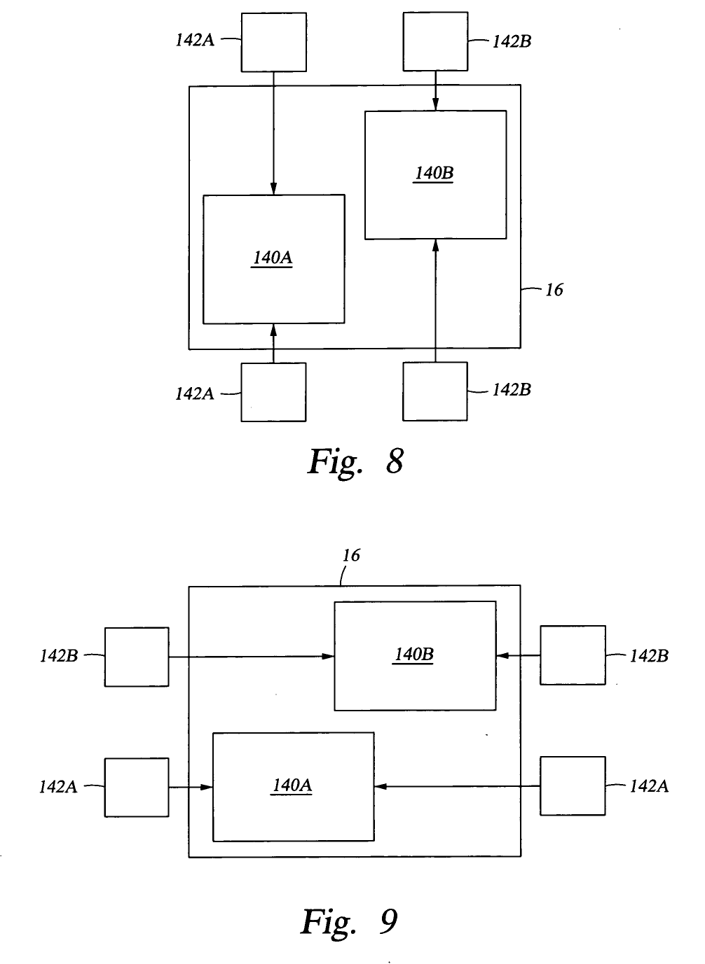

In another embodiment of the invention schematically illustrated in the plan view of FIG. 8, two rectangular magnetrons 140A, 140B are independently scanned in a single direction at the back of the rectangular target 16. For the pusher type of actuators previously discussed pairs of opposed actuators 142A, 142B are mounted on the target frame to push on opposed sides of the magnetron plates of the respective magnetrons 140A, 140B. The weight of each magnetron 140A, 140B is a fraction of the weight of a combined magnetron covering the same area, thereby reducing the required drive power or increasing the scan speed. The length of the magnetrons 140A, 140B in the scan direction can be made substantially smaller than the length of the useful scannable area of the target 16. Thereby, the weight of each magnetrons 140A, 140B is further reduced according to the ratio of magnetron length and scan length. In the absence of scanning in the transverse direction, the total widths of the magnetrons 140A, 140B in the transverse direction almost equal the width of the useful and scannable area of the target.

The one-dimensional scanning mechanism may be adapted and simplified from the arrangement of FIG. 3 by using separate set of actuators 60 aligned in a single direction for the two magnetron. The one-dimensional scanning mechanism may also be derived from the arrangement of FIG. 5. The slider plate 80 may be substituted by multiple magnetron plates directly supported on respective ones of the side rails 82, 84 and on two additional rails at the center between the two magnetron plates and parallel to the side rails 82, 84. The actuators 94, 96 and bosses are replicated for each of the magnetron plates. The transverse actuators 106, 108 and the bosses 110, 112 may be eliminated.

In the arrangement illustrated in FIG. 8, the magnetrons 140A, 140B are scanned along the short dimension of the rectangular target 16. However, as illustrated in the plan view of FIG. 9, the shapes of the magnetrons 140A, 140B can be readjusted to allow scanning along the long dimension of the target 16. The length of the magnetrons 140A, 140B along the scan direction in either embodiment may be less than half the target length or less than the scan distance. While this size relationship reduces the magnetron size and weight, it also increases the required scan distance.

More than two magnetrons may be independently scanned. As illustrated in the plan view of FIG. 10, a third magnetron 140C is added between the outer magnetrons 140A, 140B and is separately and independently moved by a pair of opposed actuators 142. One or both dimensions of the center magnetron 140C may, if desired, be different than those of the outer magnetrons 140A, 140B. The flexibility of designing the magnetron assembly with differently sized magnetrons as well as a possible different in magnetic intensity between the inner and outer magnetrons allows better differential control of the sputtering rates between the center and the two pairs of edge regions.

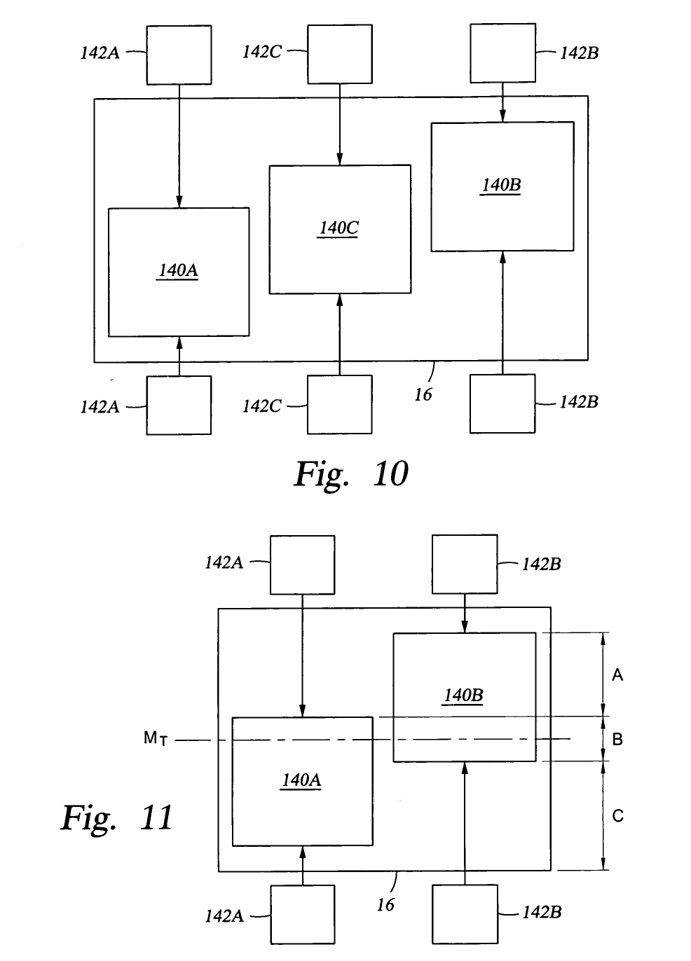

In typical operation, as illustrated in the plan view of FIG. 11. The actuators 142A, 142B reciprocally scan the two or more magnetrons 140A, 140B along the scan axis from one edge to the opposed other edge of the useful area of the target 16 although, taking into account the length of the magnetrons 140A, 14B in the scan direction, the length of the scan is substantially less than the distance between target edges. To effect the separate control, a control system 150 illustrated in the electronic control diagram of FIG. 12 has separate controls, perhaps multiplexed on a single line, for each of the pairs of actuators 142A, 142B, 142C.

Although it is not required, it is anticipated that the control system 150 typically scans the two magnetrons 140A, 140B of FIG. 11 in anti-synchronism, that is, at the same speed in a reciprocating pattern but 180° out of phase. Anti-synchronized or out-of-phase synchronized movement will be considered independent movement while synchronized motion with zero phase difference will be considered dependent movement since the magnetrons could be mechanically locked together. However, it is advantageous to divide the scanning into multiple zones, for examples three zones A, B, and C arranged along the target 16 in the scan direction. Depending where the respective magnetron 140A, 140B are located with respect to the zones A, B, and C, the control system 150 controls the actuators 142A, 142B to vary their actuation rates and hence the speed of magnetrons 140A, 140B between the zones. Particularly in the case when the multiple magnetrons are being scanned in synchronism or anti-synchronism, the DC power delivered to the target 16 from the power supply 34 may be varied between the zones A, B, and C by the control system of FIG. 12 controlling the variable DC power supply. It the power variation is to effect control of the sputtering rate or other quantity across the scan dimension of the magnetrons, the control system 150 should control the DC power supply in synchronism with the movement of the magnetrons across the target.

Both magnetron speed and target power may be varied between the zones A, B, and C.

In the case of symmetric magnetrons 140A, 140B, it is anticipated that the zones are symmetrically arranged about a medial line M_{T} of the target 16 bisecting the scan direction. And the speed and power be the same in the two outer zones A and B. However, as is evident from FIG. 4, magnetrons and especially their plasma loops need not be symmetric along the scan direction. Accordingly, the zones A, B, and C may be asymmetrical about the target median M_{M} and further the speeds and powers may be advantageously varied between the outer zones A and C.

A similar division into zones may be advantageously applied to a magnetron system having three or more independently controlled magnetrons. The separate control of the inner magnetron is effective at controlling the variations between the center and the edge of the target.

Although the described multiple magnetron scan only along parallel paths in one direction, it is possible to scan multiple magnetrons along two perpendicular directions. For example, a primary scan may extend a distance to scan each magnetron substantially across the target in one direction, a second scan may extend a lesser distance in the perpendicular direction to account for edge effects between the two or more magnetrons. One simple such scan forms a respective rectangular path for each magnetron.

It is understood that the target can divided into more than three zones. In the limit, the target power and magnetron speed can be continuously and independent varied as each of the magnetrons travel from one side to the other of the target.

Although the invention has been described with respect to sputtering display panels, the invention can applied to other substrates, such as solar cell panels or partially reflective windows. The sputtering chamber can included in a cluster-tool system, an in-line system, a stand-alone system or other system requiring one or more sputter chambers.

The lighter weight reduce the need for high-torque motors and permit installation and servicing of the magnetron and target with crane hoists rather than heavy-duty gantries.

The faster scanning speed enabled by the smaller magnetrons allow better thickness control of very thin films.

The separate control of multiple magnetrons and the allowance of variations of speed and power across the target permit tailoring of deposition thickness and/or more uniform erosion of the target.

1. A magnetron sputter reactor, comprising:
a rectangular target; and
at least two magnetrons independently movable along paths parallel to a side of said target.

2. The reactor of claim 1, wherein said at least two magnetrons are rectangular.

3. The reactor of claim 2, comprising at least three of said magnetrons.

4. The reactor of claim 1, further comprising:
at least two sets of actuators moving respective ones of said magnetrons; and
a control system separately controlling said sets of actuators.

5. The reactor of claim 4, wherein each of said sets consists of one respective actuator.

6. The reactor of claim 4, wherein each of said sets comprises two opposed actuators.

7. The reactor of claim 4, wherein said control system can control a level of actuation rate of said actuators to thereby control a speed of said magnetrons.

8. The reactor of claim 4, further comprising a variable power supply for said target and wherein said control system can control an amount of power delivered to said target in synchronism with movements of said magnetrons.

9. The reactor of claim 1, wherein said magnetrons are scannable only along one direction.

10. The reactor of claim 2, where said magnetrons are scannable along two perpendicular directions.

11. A method of sputtering material from a rectangular target onto a substrate, comprising:
independently scanning two or more magnetrons across a back of said target during a sputter deposition onto said substrate.

12. The method of claim 11, further comprising controlling a level of power delivered to said target in synchronism with said scanning of said magnetrons.

13. The method of claim 11, wherein said magnetrons are scanned only along parallel axes.

14. The method of claim 11, wherein said magnetron are scanned along respective perpendicular directions.

15. A substrate processed according to the method of claim 11.

16. In a magnetron sputter reactor having a rectangular target and a magnetron scannable in two dimensions at the back of the target, a scanning process comprising scanning said magnetron along a continuous rectangular pattern.

17. The process of claim 16, wherein said pattern includes two perpendicular sets of parallel straight paths.

18. The process of claim 16, wherein said magnetron is substantially rectangular and has effective Cartesian dimensions of between 50% and 90% of corresponding dimension of a useful area of said target.

19. The process of claim 16, wherein said pattern consists of two perpendicular sets of parallel straight paths.

20. The process of claim 16, further comprising varying an amount of power applied to the target while the magnetron is being scanned along the continuous rectangular pattern.
